(19) United States
(12) Patent Application Publication
(10) Pub. No.: US 2010/0260946 A1
(43) Pub. Date: Oct. 14, 2010

(54) Nanostructure arrays and fabrication methods therefor

(76) Inventors: Dongdong X. Jia, Lock Haven, PA (US); Anura Goonewardene, Mill Hall, PA (US)

Correspondence Address: CHARLES N. QUINN;FOX ROTHSCHILD LLP, 997 Lenox Drive, Bldg. #3, Lawrenceville, NJ, 08648, US

(21) Appl. No.: 11/645,215

(22) Filed: Dec. 22, 2006

Related U.S. Application Data
(60) Provisional application No. 60/753,807, filed on Dec. 23, 2005.

(51) Int. Cl. C23C 16/44; B05D 1/32; C23C 16/50; C23C 14/34; C23C 14/46

(52) U.S. Cl. 427/569; 427/259; 427/248.1; 427/596; 204/192.1; 204/192.11

(57) ABSTRACT

Nanorings and methods for fabrication thereof, preferably of gold and tungsten, involve deposition on silicon wafer and/or glass substrates using random incidence sputtering deposition and thermal vapor deposition techniques to produce two dimensional tungsten nanotriangle and gold nanoring arrays on the silicon wafer substrates with the size of resulting equilateral tungsten nanotriangles being about 100 nm per side and being spaced about 210 nm from each other, and with the gold nanorings being about 220 nm in diameter, 40 nm wide, 10 nm thick and being spaced about 560 nm from each other.

### CROSS REFERENCE TO RELATED PATENT APPLICATION

This patent application claims the benefit under 35 USC 119 of the filing date of U.S. provisional patent application Ser. No. 60/753,807 filed Dec. 23, 2005 in the names of Dongdong Jia and Anura Goonewardene. The disclosure of the '807 application, entitled “Multi-Dimensional Nanostructure Arrays And Methods For Fabrication And Use Thereof”, is hereby incorporated by reference in its entirety.

### BACKGROUND OF THE INVENTION

Different nanostructures exhibit different properties that are significant for practical applications. Three dimensional nanostructures with complicated shapes, such as nanorods and nanosprings, are known, as disclosed by K. Robbie and M. J. Brett, “Sculptured Thin Films and Glancing Angle Deposition: Growth Mechanics and Applications”, Journal of Vacuum Science & Technology, Volume 15, Issue 3, pp. 1460-1466 (1997), the disclosure of which is incorporated by reference, and by O. Toader and S. John, “Proposed Square Spiral Microfabrication Architecture for Large Three-Dimensional Photonic Band Gap Crystals”, Science, Volume 292, Issue 5519, pp. 1133-1135 (2001), the disclosure of which is also incorporated by reference, and by S. Y. Lin et al., “A Three-Dimensional Photonic Crystal Operating at Infrared Wavelengths”, Nature, Volume 394, Issue 6690, pp. 251-252 (1998), the disclosure of which is further incorporated by reference.

Nanostructures have important applications in organic light emitting diodes (OLED), as disclosed by T. Karabacak et al., “Sensors and Displays: Principles, Materials, and Processing—Enhanced Photoluminescence of PPV Thin Film Coated on a Nanostructured Substrate by Glancing Angle Deposition”, Electrochemical and Solid-State Letters, Volume 7, Issue 9, p. H36 (2004), the disclosure of which is incorporated by reference, and in photonic band gap crystals (PBC), as disclosed by J. G. Fleming et al., “All-Metallic Three-Dimensional Photonic Crystals with a Large Infrared Bandgap”, Nature, Volume 417, Issue 6884, pp. 52-55 (2002), the disclosure of which is also incorporated by reference.

Fabrication of these complicated three dimensional nanostructures usually requires special techniques such as glancing or oblique angle deposition (“GLAD”) using the shadow effect, as disclosed by J. Lintymer et al., “Glancing Angle Deposition to Modify Microstructure and Properties of Sputter Deposited Chromium Thin Films”, Surface & Coating Technology, Volume 174, pp. 316-324 (2004), T. Smy et al., the disclosure of which is incorporated by reference, and as disclosed in “Regular Articles—Three-Dimensional Simulation of Film Microstructure Produced by Glancing Angle Deposition”, Journal of Vacuum Science & Technology, Volume 18, Issue 5, pp. 2507-2512 (2000), the disclosure of which is additionally incorporated by reference, and by J. P. Singh et al., “Metal-Coated Si Springs: Nanoelectromechanical Actuators”, Applied Physics Letters, Volume 84, Issue 18, pp. 3657-3660 (2004), the disclosure of which is also incorporated by reference.

Most nanostructures fabricated using GLAD are somewhat uniform, but are not identical. The degree of uniformity is similar to that of grass in a lawn or that of trees in a natural forest. However, for applications such as photonic band gap crystals, more regular and uniform nanostructures are required.

To achieve this it is desirable to build regular two dimensional nanoscale arrays on a substrate; the resulting two dimensional nanoarrays can then be used as a template for growing three dimensional nanostructures using glancing angle deposition (GLAD). There are many suitable methods of making two dimensional nanoarrays; these include photo etching and chemical etching, with use of masking.

Most nanostructure fabrication uses deposition or etching methods. Etching methods include two types, photoetching and chemical etching. In photoetching, the etching source is usually an intense UV light beam with photo-resistant masks. In chemical etching, the etching source is usually a chemical solution with chemically resistant masks used to pattern nanostructures. To make complicated three dimensional nanostructures, chemical etching and photoetching can be used in combination.

Glancing angle deposition (GLAD) is a newer method to fabricate three dimensional nanostructures based on deposition processes. GLAD applies an incident flux at an angle to a rotating substrate, using the shadowing effect to form three dimensional nanostructures. The type of deposition can be any of the usual methods such as thermal vapor deposition, chemical vapor deposition, laser heated deposition and the like. These GLAD methods have been used to make two dimensional nanoarrays with nanopores, nanoholes, and nanodots, and to make three dimensional nanostructures such as nanorings, nanorods, nanosprings, nanoballs, etc.

Such nanostructures have important applications in making micro-electro-mechanical-system (MEMS) and nano-electro-mechanical-system (NEMS) devices, wave guides, photonic band gap crystals, optical high pass filters, corrugated thin films, photoluminescence and electroluminescence devices, light emitting diodes (LEDs), and organic light emitting diodes (OLEDs).

When nanostructures are made with dimensions close to the wavelength of light, new phenomena are found and new applications can be developed. At these small sizes, fabrication of nanostructures of certain defined shapes becomes very important.

Some three dimensional nanostructures are of particular interest in practical applications. For example, nanosprings are used to fabricate photonic band gap crystals in three dimensions. Metallic photonic band gap crystals are used in incandescent lamps to reduce energy loss. Theoretically, up to 60% of the infrared radiation from a incandescent lamp can be saved and the energy converted to visible light, which means an increase in energy efficiency of nearly 60%. Other structures, such as nanorods and nanosprings, can also be used for surface corrugation, increasing output efficiency.

Nanoring shapes have heretofore been obtained by deposition and by lithography methods.

### SUMMARY OF THE INVENTION

The invention embraces new methods for production of two dimensional nanoring arrays and individual nanorings. The invention further embraces the particular shape of the nanorings and their applications.

Nanorings in accordance with this invention provide important nanopatterns for development of three dimensional nanostructures. In accordance with aspects of this invention, nanorings may be fabricated as two dimensional nanotemplates. The nanorings can be used to fabricate nanomagnetic dipoles, nanoelectrical generators (nanomotors) and nanomechanical parts. If the nanorings are used to grow nanotubes with the GLAD technique, nanotubes may be fabricated in sizes ranging from 10 nm to several micrometers in diameter. With the invention, nanotubes can be grown with materials such as various oxides (which can be used for nanofluid dynamics research) and metals (which can be used for many applications such as wave guides). The invention also embraces nanotubes for use in nanofiber optics and in optical high pass filters. These three dimensional nanostructures have certain advantages over traditional carbon nanotubes in that shapes are variable and dimensions are flexible. Depending on the atoms used to construct the nanostructures, the properties may similarly be varied.

In a preferred practice of the invention, particles having certain designed or selected shapes are evenly distributed on a substrate to create a monolayer. Materials for making nanostructures are deposited on these particle layers. As atoms and/or molecules are deposited on the particles, the deposited atoms and/or molecules flow downwardly along the surfaces of the particles. These atoms and/or molecules aggregate around the feet of the particles and hence form a shape depending on the particle footprint. After removing the particles together with the residual material on the tops of the particles, a shaped nanostructure results. If the particles are distributed regularly and the layer is a uniform monolayer, a regular two dimension nanoarray results.

Pure tungsten and gold are desirably used as deposition materials.

Suitable polystyrene microspheres of 420 nm and 560 nm in diameter, with 10% solids concentration, are available from Bang Laboratory Inc.

0.2% n-dodecyl-sodium-sulfate is a preferable surfactant.

Both thermal vapor deposition and random incident sputtering deposition techniques may be desirably used.

### DESCRIPTION OF THE DRAWINGS

FIG. 1 is a 5 μm×5 μm AFM color image of a polystyrene microsphere monolayer (560 nm) on a silicon (110) substrate.

FIG. 2 on the left side is a SEM image of a tungsten nanotriangle array on a silicon (110) substrate and on the right side is a schematic graphical representation of the deposition steps used to obtain the array.

FIG. 3 on the left side is 20 μm×20 μm AFM color image of gold nanorings on a silicon (110) substrate; on the right side is the same image at 5 μm×5 μm.

FIG. 4 is a schematic representation of the cross sectional measurement of a gold nanoring using AFM. The nanoring is ˜220 nm diameter, ˜40 nm wide (full width at half maximum), and ˜10 nm thick. The inset is an enlarged version of the schematic.

FIG. 5, consisting of FIGS. 5(a) through 5(d), is a schematic representation of the steps of one method for formation of gold nanorings according to the invention. FIG. 5(a) depicts the spheres after random incidence deposition with the gold atoms depicted sliding down to the bottom exterior of the polystyrene microspheres; FIG. 5(b) depicts the gold atoms aggregated at the bottom of the microspheres and formed into a nanoring; FIG. 5(c) depicts the resulting gold nanorings remaining after removing the polystyrene microspheres with chloroform, with only the gold nanorings remaining, while FIG. 5(d) presents some of the parameters of the geometry involved with this practice of the invention.

FIG. 6 is a color photograph of gold deposited on a glass substrate, showing that after removal the polystyrene microspheres, some of the glass/gold was also somewhat removed.

Figure A is a photomicrograph, at two different magnifications, of a polystyrene microsphere monolayer that may be used in practicing the invention.

Figure B is a photomicrograph, at two different magnifications, of nanorings obtained through practice of the invention.

Figure C is a schematic depiction of gold atoms being deposited onto microspheres in accordance with the invention.

Figure D is a schematic depiction of gold atoms moving downwardly along the surfaces of microspheres after being deposited thereon, in accordance with the invention.

Figure E is a schematic depiction of gold nanorings formed at the bases of microspheres, after having moved downwardly along the surfaces of microspheres subsequent to deposition thereon, in accordance with the invention.

Figure F on the left is a schematic depiction of gold nanorings arrays resulting after removal of microspheres and on the right is a geometric analysis of the AFM results achieved, in accordance with the invention.

### DESCRIPTION OF THE INVENTION AND BEST MODE KNOWN FOR PRACTICE THEREOF

One aspect of the invention involves a method for nanotemplate fabrication using sputtering and monolayer methods in combination, as generally described below.

In one practice of the method, a monolayer of microspheres was prepared on a polished single sided (110) Si wafer and an atomic force microscope (AFM) image was obtained.

A sputtering and a monolayer method in combination was used to fabricate a nanotemplate. Two dimensional nanoring arrays resulted on an Si substrate. The results were confirmed for different samples by AFM images

The AFM was used again to confirm the results with different samples; nanorings were found in all samples.

Specifically, a flat polished silicon wafer was used as a substrate. The wafer was cleaned using the RCA method. Polystyrene microspheres were used to make monolayer coatings on top of the Si substrate. The microspheres were suspended in distilled water at 2% solids concentration. The microspheres were distributed evenly onto the silicon substrate using a 5 ml syringe. After 10 minutes of exposure to air, semi-dry single or multiple layers of polystyrene microspheres formed. The silica substrate with the microsphere coating was then dipped into distilled water. A monolayer of microspheres was obtained using n-Dodecyl-sodium sulfate solution. Water was removed using 5 ml and 10 μl syringes.

A substrate carrying the microsphere monolayer was mounted in a sputter deposition chamber. A thin gold layer was sputter deposited onto the monolayer and the substrate. The substrate was then put into a chloroform solution for two days. The chloroform dissolved the polystyrene microspheres. Dissolution of the polystyrene microspheres resulted in removal of the gold layer by fracture and dissolution on top of the microspheres, leaving a regular two dimensional nanoring array behind.

### Example A

Polystyrene microspheres were evenly distributed and a monolayer was formed using n-dodecyl-sodium sulfate on a silicon (110) single side polished wafer, as illustrated in Figure A. A uniform monolayer was obtained over about 2 to 4 square millimeter area. A larger, ordered area was obtained on a quartz double-sided polished wafer.

Next, sputter deposition was used with non-normal incidence to deposit a 20 nm gold layer onto the monolayer of microspheres. The microspheres were then removed using chloroform. As the microspheres were removed, the chloroform also removed the gold layer that was on top of the microspheres, leaving behind nanoring arrays, as shown in Figure B.

As the atoms of gold reach the spheres arranged in a monolayer with a non-normal incidence, the atoms of gold cannot go directly to the bottom, namely to the substrate, through the interstices between the spheres. This is illustrated in Figure C.

Due to gravitational force the gold atoms do not stay on top of the spheres but slide down along the spherical surface to the bottom, and aggregate there. This is illustrated in Figure D.

The atoms that reach the foot of the microspheres form a ring shaped structure, as illustrated in Figure E; that is the footprint of the microspheres.

After removing the polystyrene microspheres with chloroform, regular nanoring arrays result, as depicted schematically in Figure F and as shown in Figure B.

### Example 1

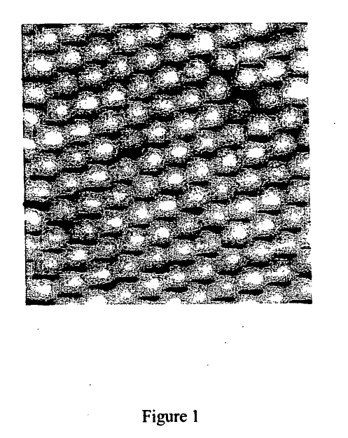

Polystyrene microspheres with sizes as described above were diluted to about 1% solid solution, and then dropped onto a silicon/glass substrate and spread over the substrate. Next a drop of 0.2% n-dodecyl-sodium-sulfate to act as a surfactant was dropped onto the substrate in accordance with the teachings of Z. P. Huang et al., “Growth of large periodic arrays of carbon nanotubes”, Applied Physics Letters, Volume 82, Issue 3, pp. 460-463 (2003), the disclosure of which is incorporated by reference. The polystyrene microspheres spread well and formed a monolayer of about 3×3 mm due to the effect of the surfactant. Water was removed using a 10 μl syringe. When the water was removed, a monolayer remained on the substrate as shown in FIG. 1. The 420 nm diameter polystyrene microspheres were put on a silicon (110) wafer substrate and used for tungsten deposition. The 560 nm diameter polystyrene microspheres were put on silicon (110) wafer and glass substrates and used for gold deposition.

The substrates with 420 nm polystyrene microsphere monolayers were put into a thermal vapor deposition chamber for tungsten deposition. A 20 nm tungsten layer was deposited onto the substrates. The thickness of the deposition was regulated by controlling deposition time. Deposition rate was monitored using a quartz oscillator.

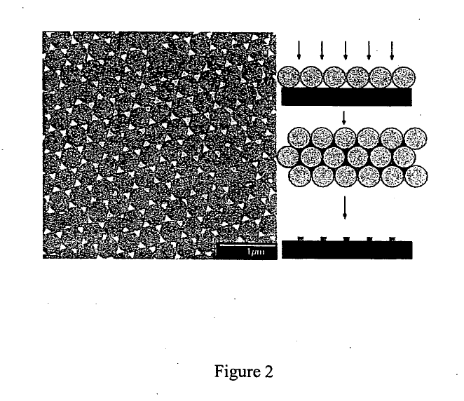

After deposition, the polystyrene microsphere monolayer was removed using chloroform. Nanotriangle arrays of tungsten resulted, as shown in FIG. 2. The right hand side of FIG. 2 shows that tungsten was deposited in the interstices among the polystyrene microspheres as well as on the top surface of the polystyrene microspheres. When the polystyrene microsphere monolayer was removed, the tungsten deposited on top of this layer was also removed, leaving only the tungsten deposited in the interstices to form the nanotriangle arrays. The tungsten nanotriangles were generally in the form of equilateral triangles with 100 nm sides. They were about 420 nm apart.

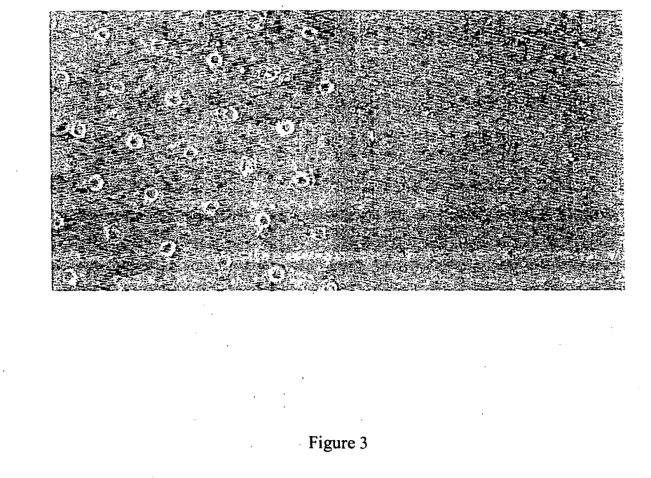

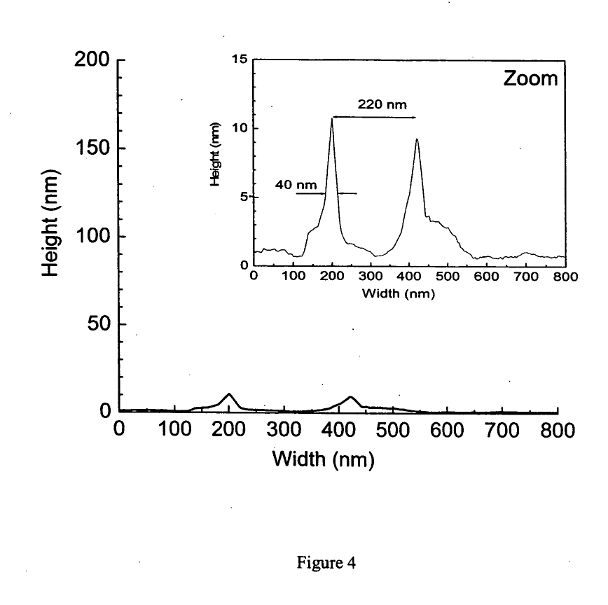

Gold was deposited onto the 560 nm polystyrene microsphere monolayer using random incidence sputtering deposition: 20 nm thick gold was deposited for 3 minutes at a deposition rate of 6.7 nm/minute. Microspheres were removed by chloroform after deposition. Gold nanoring arrays formed on the silicon wafer substrate, as shown in FIG. 3. The nanorings spacing was about 560 nm apart, indicating that the nanorings formed at the foot of each of the polystyrene microspheres. The shape of a typical nanoring, which was about 220 nm diameter, 40 nm thick and about 10 nm high, is shown in FIG. 4.

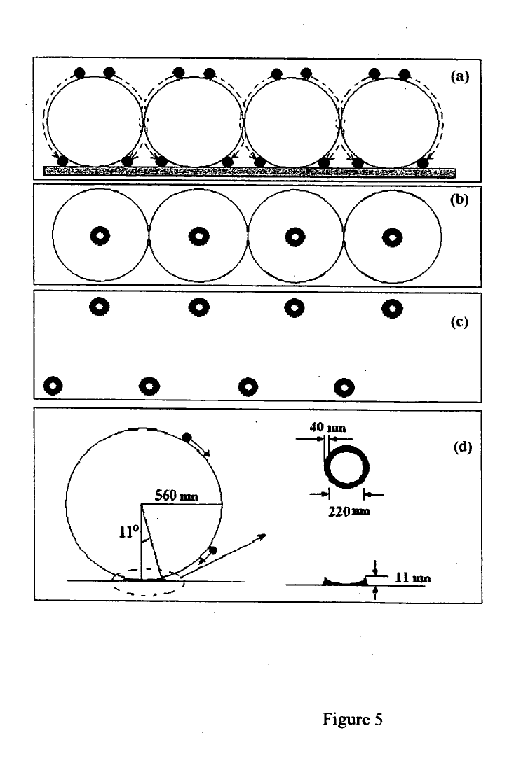

FIG. 5 is schematic representation of the nanoring formation. The deposition was not a normal incidence deposition. As a result, the gold atoms/ions were not very well deposited into the interstices among the polystyrene microspheres. Most of the gold was deposited on top of the polystyrene microsphere monolayer.

Gold has a bond length of 1.34 Å which is just next to Hg, which as a bond length 1.49 Å. Pure gold is soft and easily deformed because the bonding between gold atoms is not as strong as other metals. This may be the reason that some gold ions and atoms do not remain bonded to each other on the polystyrene microsphere top surfaces, and slide down to the bottoms of the polystyrene microspheres. Aggregation of these atoms or ions forms a ring shape structure around the foot of each polystyrene microsphere. After the polystyrene microspheres were removed by chloroform, the nanoring array remained.

Analysis of this was carried out using AFM. The dimensions obtained matched the dimensions that were measured by using AFM as shown in FIG. 4. The other evidence supporting the success of this result was that Pt (bond length 1.30 Å) deposition was tried in the same way. After removing the monolayer, a blank substrate resulted.

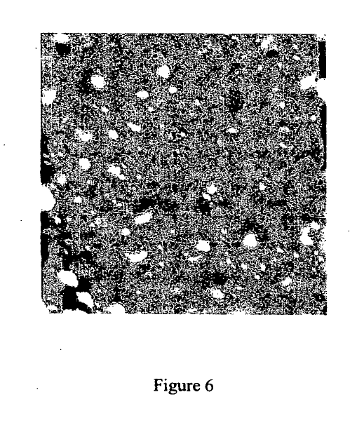

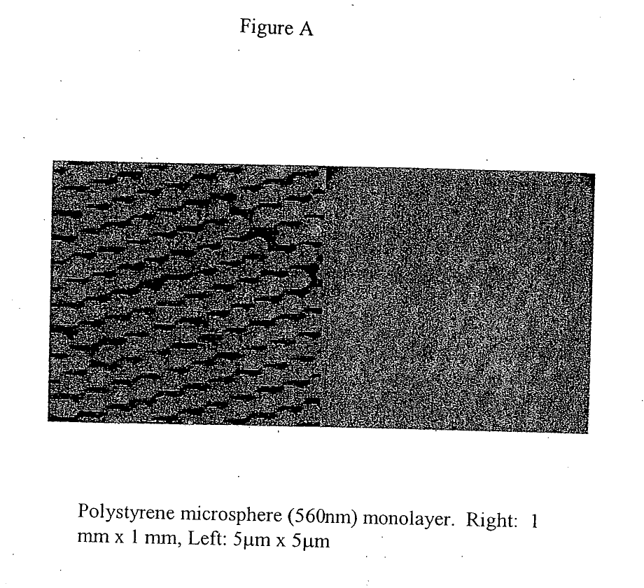

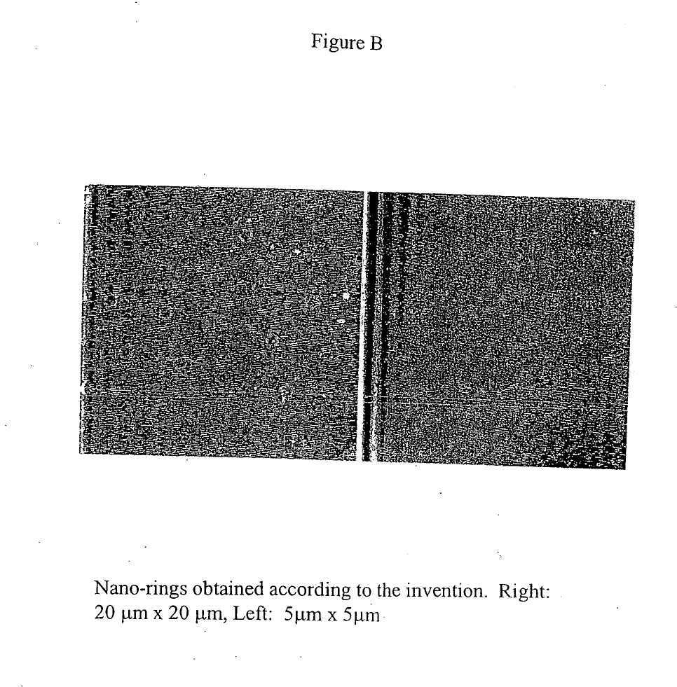

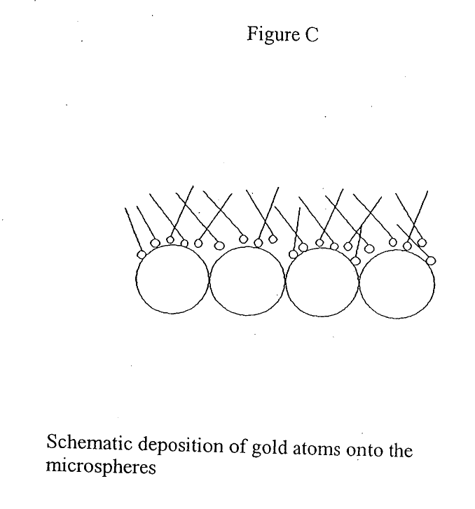

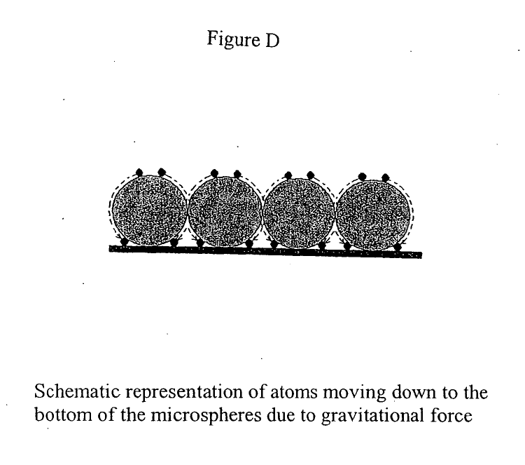

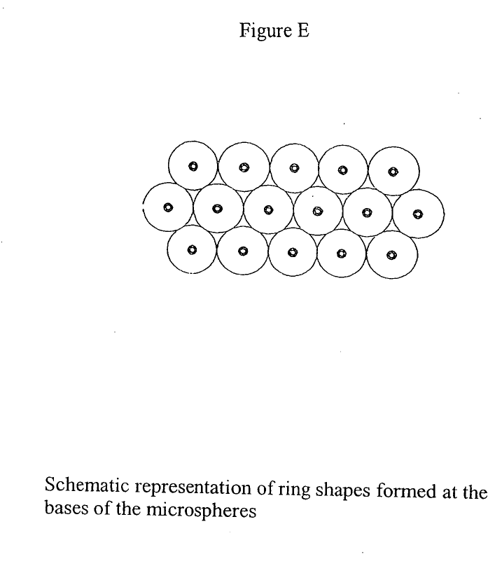

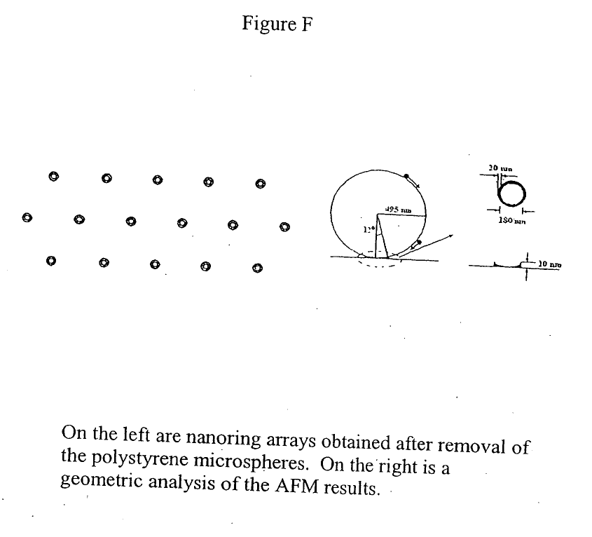

No gold nanorings were observed on the glass substrate. Instead, some structures resulted, appearing to have size on the order of the nanorings, as shown in FIG. 6. These were etched ring-like marks with diameter of ˜250 nm on the glass substrate. The reason this kind of structure resulted may be that the gold/glass/polystyrene/chloroform mixture reacted and provided an etching effect instead of deposition. This is possible because gold is more reductive as compared with the silicon in the glass substrate.

This exemplary practice of the invention resulted in successful fabrication of two dimensional tungsten nanotriangle and gold nanoring arrays with different deposition techniques, using a polystyrene microsphere monolayer as a mask. These regular two dimensional nanoarrays are important templates for fabricating three dimensional nanostructures using techniques such as GLAD.

The invention further embraces the materials that have been used to make the nanorings and those materials that could be used to make nanoshapes using the disclosed methods. The materials listed include preferred and other acceptable substrate materials, particle materials for monolayer fabrication, suitable materials for fabrication into rings and other shapes of interest, and chemicals used in the process.

The substrate may be a silicon wafer, a quartz wafer, a glass slide, a bulk material surface, a coated surface, and the like, including any other substrate that can be used to receive a monolayer array of particles.

The particles can be polystyrene microspheres, SiO₂ balls, or any other material spheres that are nanoscale (5 nm-500 nm) diameter or micro-scale (500 nm-500 μm) diameter and/or dimensioned as to height, length and width. The individual particles can be cubic, spherical, rectangular, triangular, regular and/or irregular, uniform and/or non-uniform, single phase and/or multiple phase, pure matter and/or compounds and/or composites, and the like. The particles may include any type of pre-coating for stabilizing, insulating, shaping, etc.

The nanoring materials may be pure precious metals such as gold, silver and platinum, metallic alloys such as Ag/Au, Ag/Ni, semiconductors such Si, ZnS, ZnO, CaS, GaAs, etc., insulators, and other compounds such as MgO, Al₂O₃, Y₃Al₅O₁₂ (YAG), etc.

Chemicals that can be used to assist the formation of any intermediate products as disclosed herein may be, for example, n-dodecyl-sodium sulfate, acetone, methanol, alcohol ethanol, distilled water, etc., in liquid and/or solid and/or gas forms. Suitable chemicals that can be used to remove the particles and/or deposition layers include chloroform, acetone, methanol, ethanol, and similar, preferably chemically related solvents.

Another aspect of the method of this invention is the process of forming a monolayer of particles (with particle dimensions of from 5 nm to 500 μm), and depositing materials (the actual nanoring materials) onto a monolayer, to allow the particulates in the form of atoms and/or molecules and/or conglomerates and/or clusters and/or particles to fall to the bottom of the monolayer due to the force of gravity, to form a ring shape structure on a scale of from 10 nm to 100 μm outer diameter and from 5 nm to 100 μm inner diameter, after which the monolayer is removed together with the coating on top of the particulates. The resulting structures are the desired nanorings or micro-rings. The invention further embraces any nanorings or micro-rings, and nanoring or micro-ring arrays, that are fabricated according to the procedure described above.

In practicing this aspect of the invention, initially, the particles are preferably placed in a suspension. The suspension can be any type of liquid such as distilled water, which is preferred as described above respecting the suitable materials.

Next, the particle suspension is distributed evenly onto the substrate to form a thin layer, namely the monolayer. Any tools that can lead to an even distribution of particles may be used such as syringes and nozzles. The preferred substrate and chemicals are selected from those described above.

Thereafter, the materials used to form the rings are coated onto the monolayer substrate. Among the coating/deposition methods that may be used are pulsed laser deposition (PLD), chemical vapor deposition (CVD), thermal vapor deposition (TVD), molecular beam epitaxy (MBE), sputtering, electron beam sputtering, and the like. Any method that generates a flux of small particles such as plasma, atoms, ions, molecules, clusters, etc., and that guides these particles onto the substrate surface, using any incidence angle that results in deposition, may be used.

Lastly, the particle monolayer is removed together with the deposition on top of the particles. Use of any of the chemicals recited herein to remove the particles and the deposition layer on top of the particles is within the scope of the invention.

The invention further embraces any pretreatment and/or any after-treatment of the substrate, particles, chemicals and/or the resulting mid-step product, where the function and desired result is to lift the resulting rings away from the substrate, as well as coating materials that have been introduced to the rings to make any structures and/or accomplish other functions, including, for example, (i) coating materials applied to the substrate before making thin particle layers, which may allow easier lifting of the rings from the substrate, (ii) using ring materials as photo/chemical resistance materials to do photo/chemical etching to make structures such as nanotubes, (iii) using rings as a template to fabricate structures by methods such as GLAD, (iv) sealing holes to make nanobowis, etc.

The invention also embraces use of the individual/regular arrays and/or irregular arrays of rings produced by the method for use in applications such as nanomotors, micro-motors, etc.

Shapes of the final product produced using the methods described above may be circular, square, rectangular, triangular, regular or irregular, depending on the shape of the particles used to create the monolayer. For example, a cubic particle will produce a square frame.

The invention still further embraces any shape that can be made according to the methods described herein. This specifically includes regular shapes, namely circular rings, square frames, rectangular frames, triangular frames, elliptical rings, and bowl-shaped structures with any curvature. The dimensions of the individual structures may vary from 5 nm to 500 μm.

The resulting structures may have a crystalline and/or polycrystalline and/or amorphous characteristics.

The following is claimed:

1) A method for fabricating nanorings, comprising:
a) diluting microspheres of preselected size and shape into liquid to form a solution;
b) dropping the solution onto a substrate;
c) removing the liquid from the substrate;
d) depositing a metallic layer on the microspheres residing on the substrate; and
e) removing the microspheres from the substrate to leave nanostructures thereon formed where the microspheres had been with the nanorings having shape corresponding to the bottoms of the microspheres that contacted the substrate as the metallic layer was deposited thereon.

2) The method of claim 1 further comprising applying a surfactant to the solution resident on the substrate to encourage spread of the microspheres thereover prior to removal of the liquid from the substrate.

3) The method of claim 1 further comprising the step of controlling thickness of the metallic layer deposited on the microspheres by regulating the duration of the deposition step.

4) The method of claim 1 wherein the step of removing the microspheres further comprises applying a materials that is a solvent as respecting the material of the microspheres to dissolve the microspheres.

5) The method of claim 4 wherein the solvent is selected from the group comprising chloroform, acetone, methanol, and ethanol.

6) The method of claim 1 wherein the metal for the metallic layer is selected from the group consisting of gold, silver and platinum.

7) The method of claim 1 wherein the metallic layer is tungsten.

8) The method of claim 1 wherein the metallic layer is an oxide of a metal.

9) The method of claim 1 wherein the metal for the metallic layer is an alloy selected from the group comprising silver-gold alloys and silver-nickel alloys.

10) The method of claim 1 wherein the material for the microspheres is selected from the group consisting of silicon dioxide and plastic.

11) The method of claim 10 wherein the plastic is polystyrene.

12) The method of claim 11 wherein the microspheres are substantially between about 420 and about 560 nanometers in diameter.

13) The method of claim 10 wherein the microspheres are substantially between about 5 nanometers and about 500 micrometers in diameter.

14) The method of claim 2 wherein the surfactant is a sodium sulfate solution.

15) The method of claim 1 wherein depositing the metallic layer is performed by random incident sputtering.

16) The method of claim 1 wherein depositing the metallic layer is performed by vapor deposition.

17) The method of claim 16 wherein depositing the metallic layer is performed by thermal vapor deposition.

18) The method of claim 16 wherein depositing the metallic layer is performed by pulsed vapor deposition.

19) The method of claim 16 wherein depositing the metallic layer is performed by chemical vapor deposition.

20) The method of claim 1 wherein depositing the metallic layer is performed by electron beam sputtering.

21) The method of claim 1 wherein depositing the metallic layer is performed by molecular beam epitaxy.

22) The method of claim 1 wherein depositing The metallic layer is performed by generating a flux of small particles selected from the group consisting of plasmas, atoms, ions, molecules and clusters, and guiding those particles towards the substrate at an incidence angle resulting in deposition.

23) The method of claim 1 wherein the solution is from about 1 to 2 percent solids by weight.

24) The method of claim 1 wherein the substrate is selected from the group consisting of silicon and glass.

25) A method for fabricating nanorings, comprising:
a) diluting polystyrene microspheres having diameters between about 420 and about 560 nanometers into water to form a solution of about 2% solids by weight;
b) dropping the solution onto a silicon substrate;
c) applying a surfactant to the solution resident on the substrate to encourage spread of the microspheres thereover;
d) allowing the solution liquid to evaporate leaving the microspheres on the substrate;
e) sputter depositing gold particles on the microspheres residing on the substrate to a thickness of about 20 nanometers and allowing the particles to flow downwardly along and around the microspheres to the substrate; and
f) dissolving the microspheres by application of chloroform thereto to leave metallic particle nanorings formed on the substrate about the substrate area that had been contacted by the microspheres resting thereon.

26) A method for fabricating nanostructures, comprising:
a) creating a soluble template corresponding in shape to that of the nanostructure of interest and that is inert to metallic deposition on a horizontal surface of an inert substrate;
b) depositing material selected from the group consisting of gold, tungsten and metallic oxides on the template by random incident sputtering; and
c) dissolving the template by application of a solvent thereto, leaving the deposited material forming the nanostructure of interest on the substrate.

27) A method for fabricating nanorings, comprising:
a) diluting microspheres of preselected size and shape into liquid to form a solution;
b) dropping the solution onto a substrate;
c) removing the liquid from the substrate;
d) depositing a layer of material selected from the group consisting of Si, ZnS, ZnO, CaS, GaAs, MgO, Al₂O₃ and Y₃Al₅O₁₂ on the microspheres residing on the substrate; and
e) removing the microspheres from the substrate to leave nanorings thereon formed of the selected material where the microspheres had been with the nanorings having shape corresponding to the bottoms of the microspheres that contacted the substrate as the layer of selected material was deposited thereon.

28) A method for fabricating nanostructures, comprising:
a) mixing microparticles of preselected size and shape in liquid to form a solution;
b) applying the solution to a substrate;
c) removing the liquid from the solution on the substrate;
d) depositing a layer of a selected material on the microparticles remaining on the substrate; and
e) removing the microparticles from the substrate to leave nanostructures thereon formed of the selected material where the bases of the microparticles had contacted the substrate, with the nanostructures having shape corresponding to the selected shape of the portions of the microparticles that contacted the substrate as the layer of selected material was deposited thereon.
